(19) United States
(12) Patent Application Publication
(10) Pub. No.: US 2012/0167964 A1
(43) Pub. Date: Jul. 5, 2012

(54) STACKED PHOTOVOLTAIC CELL MODULE

(75) Inventors: Hsin-Rong Tseng, Tainan City (TW); Chun-Liang Lin, New Taipei City (TW)

(73) Assignee: AU OPTRONICS CORPORATION, Hsinchu (TW)

(21) Appl. No.: 13/073,966

(22) Filed: Mar. 28, 2011

(30) Foreign Application Priority Data
Dec. 31, 2010 (TW) 99147247

(51) Int. Cl. H01L 31/06

(52) U.S. Cl. 136/255

(57) ABSTRACT

A stacked photovoltaic cell module including a substrate, a first electrode layer on the substrate, a first carrier transport layer on the first electrode layer, a first light absorption layer on the first carrier transport layer, a second electrode layer on the first light absorption layer, a first output unit electrically connected to the first electrode layer and the second electrode layer, a second carrier transport layer on the second electrode layer, a second light absorption layer on the second carrier transport layer, a third electrode layer on the second light absorption layer, and a second output unit electrically connected to the second electrode layer and the third electrode layer. The second carrier transport layer and the second light absorption layer satisfy Φ1+Φ2−2π(n1D1+n2D2)/λ=2 mπ.

### CROSS-REFERENCE TO RELATED APPLICATION

This application claims the priority benefit of Taiwan application Ser. No. 99147247, filed Dec. 31, 2010. The entirety of the above-mentioned patent application is hereby incorporated by reference herein and made a part of this specification.

### BACKGROUND OF THE INVENTION

1. Field of the Invention

The invention relates to a photovoltaic cell module and more particularly to a stacked organic photovoltaic (OPV) cell module.

2. Description of Related Art

With the consideration of environmental protection in recent years, the developments of alternative energy and renewable energy have become popular in response to the shortage of fossil energy and to reduce the impact on environment caused by the use of fossil energy. Herein, photovoltaic cells attract the most attention among the alternative energy and renewable energy. Photovoltaic cells are capable of converting solar energy into electric energy directly without polluting the environment by generating hazardous substances such as carbon dioxide or nitride in the power generation process.

Conventionally, a first electrode layer, an active layer, and a second electrode layer are formed on a substrate in a traditional photovoltaic cell. When a light beam irradiates the photovoltaic cell, the active layer generates free electron-hole pairs under the effect of light energy. Moreover, the electrons and the holes move toward two electrode layers respectively through an electric field between the two electrode layers so as to generate a storage state of electric energy. When a load circuit or an electronic device is disposed additionally, electric energy can be provided to drive the circuit or the device.

However, the main problem of photovoltaic cells is the limitation in light absorption rate or electric energy output power. Therefore, the enhancement in light absorption rate and output power of photovoltaic cells has been developed extensively.

### SUMMARY OF THE INVENTION

The invention is directed to a stacked photovoltaic cell module capable of enhancing light absorption rate and output power of photovoltaic cells, thereby increasing the overall performance of the photovoltaic cell module.

The invention is directed to a stacked photovoltaic cell module including a substrate, a first electrode layer disposed on the substrate, a first carrier transport layer disposed on the first electrode layer, a first light absorption layer disposed on the first carrier transport layer, a second electrode layer disposed on the first light absorption layer, a first output unit electrically connected to the first electrode layer and the second electrode layer, a second carrier transport layer disposed on the second electrode layer, a second light absorption layer disposed on the second carrier transport layer, a third electrode layer disposed on the second light absorption layer, and a second output unit electrically connected to the second electrode layer and the third electrode layer. Particularly, the second carrier transport layer has a first refraction index n1 and a first thickness D1, the second light absorption layer has a second refraction index n2 and a second thickness D2, and the second carrier transport layer and the second light absorption layer satisfy: Φ1+Φ2−2π(n1D1+n2D2)/λ=2 mπ. Herein, Φ1 represents a reflective phase difference between the second light absorption layer and the third electrode layer, Φ2 represents a reflective phase difference between the second carrier transport layer and the second electrode layer, λ represents an absorption wavelength of the second light absorption layer and m represents 0 or an integer.

In light of the foregoing, in the stacked photovoltaic cell module of the invention, the second carrier transport layer and the second light absorption layer satisfy Φ1+Φ2−2π(n1D1+n2D2)/λ=2 mn, where Φ1 represents the reflective phase difference between the second light absorption layer and the third electrode layer, Φ2 represents the reflective phase difference between the second carrier transport layer and the second electrode layer, λ represents the absorption wavelength of the second light absorption layer and m represents 0 or an integer. Thus, an optical resonance cavity is formed between the third electrode layer and the second electrode layer so as to increase the light absorption rate of the second light absorption layer. Additionally, each of the photovoltaic cell units in the stacked photovoltaic cell module of the invention is connected to a corresponding output unit individually. Consequently, the first light absorption layer and the second light absorption layer can each reach its maximum light absorption rate when a light beam irradiates the photovoltaic cell module without considering the current-matching between two photovoltaic cell units, such that the total output power of the stacked photovoltaic cell module can be enhanced.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIG. 1 illustrates a schematic diagram of a stacked photovoltaic cell module according to an embodiment of the invention.

FIG. 2 illustrates a schematic diagram of a stacked photovoltaic cell module according to an embodiment of the invention.

FIG. 3 is a curve diagram showing an absorption wavelength of a stacked photovoltaic cell module according to an embodiment of the invention.

FIG. 4 illustrates a schematic top view of a stacked photovoltaic cell module according to an embodiment of the invention.

FIG. 5 is a cross-sectional diagram taken along line I-I′ and line II-II′ in FIG. 4.

FIG. 6 is a curve diagram showing a light absorption rate and an absorption wavelength of a photovoltaic cell module in a comparative embodiment.

FIG. 7 is a curve diagram showing a light absorption rate and an absorption wavelength of a photovoltaic cell module according to an embodiment of the invention.

### DESCRIPTION OF EMBODIMENTS

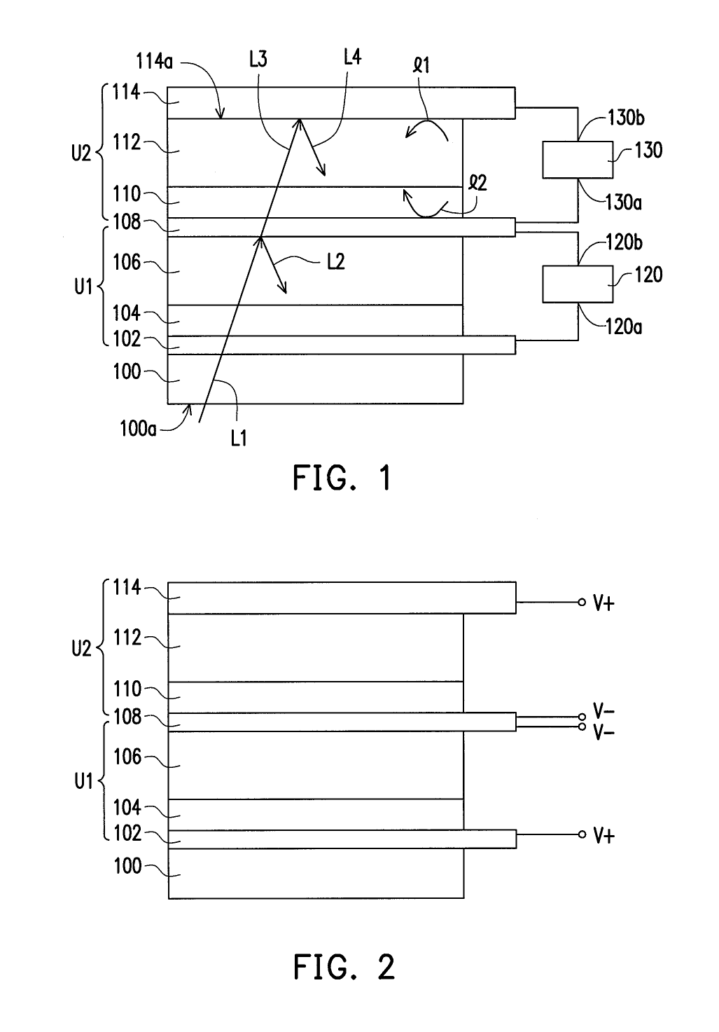

FIG. 1 illustrates a schematic diagram of a stacked photovoltaic cell module according to an embodiment of the invention. Referring to FIG. 1, a stacked photovoltaic cell module 10 of the present embodiment includes a substrate 100, a first electrode layer 102, a first carrier transport layer 104, a first light absorption layer 106, a second electrode layer 108, a second carrier transport layer 110, a second light absorption layer 112, a third electrode layer 114, a first output unit 120, and a second output unit 130.

The substrate 100 is a rigid substrate (i.e. a glass substrate) or a flexible substrate (i.e. an organic polymer substrate). When the substrate 100 adopts a flexible substrate, the stacked photovoltaic cell module 10 of the present embodiment can be fabricated using a roll to roll process.

The first electrode layer 102 is disposed on the substrate 100. According to the present embodiment, the first electrode layer 102 includes a transparent electrode material, for example, an indium tin oxide (ITO), an indium zinc oxide (IZO), an aluminum tin oxide (ATO), an aluminum zinc oxide (AZO), an indium gallium zinc oxide (IGZ), or other suitable metal oxide.

The first carrier transport layer 104 is disposed on the first electrode:layer 102. The carrier transport layer 104 is mainly used to transport carriers generated by the first light absorption layer 106 to the first electrode layer 102. The first carrier transport layer 104 can also be further adopted for the first electrode layer 102 to have a suitable work function relative to the first light absorption layer 106. According to an embodiment, the first carrier transport layer 104 is fabricated using, for example, cesium carbonate (Cs₂CO₃), Poly(3,4-ethylenedioxythiophene): poly(styrenesulfonate) (PEDOT: PSS), zinc oxide (ZnO), or other carrier transport material. The first carrier transport layer 104 has a thickness ranging from about 20 nanometer (nm) to about 100 nm, for instance.

The first light absorption layer 106 is disposed on the first carrier transport layer 104. The first light absorption layer 106 absorbs light beams with a first wavelength range. According to the present embodiment, the first light absorption layer 106 is fabricated with an organic light absorption material and mainly absorbs light beams of visible light wavelengths (i.e. light beams ranging from about 300 nm to about 700 nm) or light beams of infrared light wavelengths (i.e. light beams ranging from about 600 nm to about 1100 nm). The first light absorption layer 106 has a thickness ranging from about 60 nm to about 100 nm, for instance.

Herein, when the first light absorption layer 106 absorbs light beams of visible light wavelengths (i.e. light beams ranging from 300 nm to 700 nm), a material thereof can include poly(3-hexylthiophene): [6,6]-phenyl-C61-butyric acid methyl ester (P3HT:[60]PCBM), poly[2-methoxy-5-(30,70-dimethyloctyloxy)-1,4-phenylenevinylene]: [6,6]-phenyl-C61-butyricacidmethyl ester (MDMO-PPV:[60]PCBM), or other suitable material.

When the first light absorption layer 106 absorbs light beams of infrared light wavelengths (i.e. light beams ranging from about 600 nm to about 1100 nm), a material thereof can include poly[2,6-(4,4-bis-(2-ethylhexyl)-4H-cyclopenta[2,1 -b;3,4-b′]dithiophene)-alt-4,7-(2,1,3-benzothiadiazole)]: [6,6]-phenyl-C71 butyric acid methyl ester (PCPDTBT: [70]PCBM), poly[4,8-bis-substituted-benzo[1,2-b:4,5-b′]dithiophene-2,6-diyl-alt-4-substituted-thieno [3,4-b]thio-phene-2,6-diyl]:[6,6]-phenyl-C71 butyric acid methyl ester (PBDTTT:[70]PCBM), or other suitable material.

The second electrode layer 108 is disposed on the first light absorption layer 106. The second electrode layer 108 includes a metal material, for example, silver, aluminum, or other metal material. According to the present embodiment the second electrode layer 108 has a reflectivity ranging from about 40% to about 80% and a thickness ranging from about 10 nm to about 25 nm.

The second carrier transport layer 110 is disposed on the second electrode layer 108. The second carrier transport layer 110 is mainly adopted to transport carriers generated by the photovoltaic cell to the electrode layer. Similarly, the second carrier transport layer 110 can also be further adopted for the second electrode layer 108 to have a suitable work function relative to the second light absorption layer 112. According to an embodiment, the second carrier transport layer 110 is fabricated using, for example, (Cs₂CO₃), ZnO, (PEDOT: PSS), molybdenum oxide (MoO₃), or other suitable material. The second carrier transport layer 110 has a thickness ranging from about 50 nm to about 150 nm.

The second light absorption layer 112 is disposed on the second carrier transport layer 110. The second light absorption layer 112 absorbs light beams with a second wavelength range. According to the present embodiment, the second light absorption layer 112 is fabricated with an organic light absorption material and mainly absorbs light beams of infrared light wavelengths (i.e. light beams ranging from about 600 nm to about 1100 nm) or light beams of visible light wavelengths (i.e. light beams ranging from about 300 nm to about 700 nm). When the second light absorption layer 112 absorbs light beams of visible light wavelengths (i.e. light beams ranging from about 300 nm to about 700 nm), a material thereof can include P3HT:[60]PCBM, MDMO-PPV:[60]PCBM, or other suitable material. When the second light absorption layer 112 absorbs light beams of infrared light wavelengths (i.e. light beams ranging from about 600 nm to about 1100 nm), a material thereof can include PCPDTBT:[70]PCBM), PBDTTT:[70]PCBM, or other suitable material.

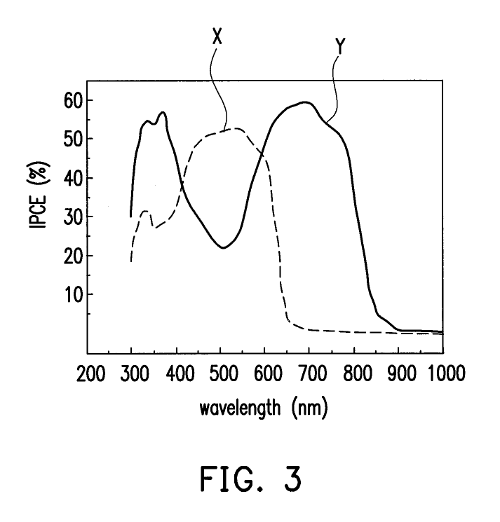

It should be noted that the second light absorption layer 112 and the first light absorption layer 106 of the present embodiment absorb light beams of different wavelength ranges. As depicted in FIG. 3, the vertical axis represents an incident photon-to-electron conversion efficiency (IPCE (%)) and the horizontal axis represents wavelength. When the first light absorption layer 106 absorbs light beams of visible light wavelengths (i.e. curve X), then the second light absorption layer 112 absorbs light beams of infrared light wavelengths (i.e. curve Y). Conversely, when the first light absorption layer 106 absorbs light beams of infrared light wavelengths (i.e. curve Y), then the second light absorption layer 112 absorbs light beams of visible light wavelengths (i.e. curve X).

The third electrode layer 114 is disposed on the second light absorption layer 112. The third electrode layer 114 includes a reflective electrode material and preferably a metal material having high conductivity and high reflectivity, for instance, aluminum, silver, or an alloy thereof.

In particular, in the present embodiment, the second carrier transport layer 110 has a first refraction index n1 and a first thickness D1, the second light absorption layer 112 has a second refraction index n2 and a second thickness D2, and the second carrier transport layer 110 and the second light absorption layer 112 satisfy:

Φ1+Φ2−2πn1D1+n2D2)/λ2 mπ

Φ1: a reflective phase difference between the second light absorption layer 112 and the third electrode layer 114

Φ2: a reflective phase difference between the second carrier transport layer 110 and the second electrode layer 108

λ: an absorption wavelength of the second light absorption layer 112.

m: 0 or an integer

Accordingly, in the stacked photovoltaic cell module, a surface 100a of the substrate 100 is utilized as a light incident surface of the stacked photovoltaic cell module. Moreover, a surface 114a of the third electrode layer 114 is used as a light reflective surface of the stacked photovoltaic cell module. Therefore, when an external light beam L1 enters the stacked photovoltaic cell module from the light incident surface 100a, light beams of the first wavelength range are absorbed when the light beam L1 passes through the first light absorption layer 106. After the light beam L1 reaches the second electrode layer 108, as the second electrode layer 108 has a reflectivity of about 40% to about 80%, a portion of a light beam L2 is reflected and light beams with the first wavelength range of the reflected light beam L2 passes through the first light absorption layer 106 again so as to be absorbed. Another portion of a light beam L3 passes through the second electrode 108 to enter the second light absorption layer 112, so that light beams with the second wavelength range of the light beam L3 are absorbed by the second light absorption layer 112. Further, the light beam L3 is reflected by the third electrode layer 114, such that a light beam L4 being reflected passes through the second light absorption layer 112 again. Consequently, light beams with the second wavelength range of the light beam L4 are absorbed by the second light absorption layer 112 once again.

It should be noted that the second carrier transport layer 110 and the second light absorption layer 112 of the present embodiment satisfy Φ1+Φ2−2π(n1D1+n2D2)/λ=2 mπ. Herein, Φ1 represents the reflective phase difference between the second light absorption layer 112 and the third electrode layer 114, Φ2 represents the reflective phase difference between the second carrier transport layer 110 and the second electrode layer 108, λ represents the absorption wavelength of the second light absorption layer 112 and m represents 0 or an integer. An optical resonance cavity is thus formed between the second electrode layer 108 and the third electrode layer 114. In other words, when the reflected light beam L4 passes through the second light absorption layer 112 so as to reach the second electrode layer 108, the light beam L4 is reflected by the second electrode layer 108 again. Therefore, the light beam is reflected repetitively between the third electrode layer 114 and the second electrode layer 108 (as depicted by light beams 11 and 12) and absorbed by the second light absorption layer 112 repetitively. Since the light beam can be reflected between the third electrode layer 114 and the second electrode layer 108 repetitively and absorbed by the second light absorption layer 112 repetitively, the absorption for light beams with the second wavelength range by the second light absorption layer 112 can be increased.

According to the present embodiment, the stacked photovoltaic cell module aforementioned further includes a first output unit 120 and a second output unit 130. The first output unit 120 has a first electrode end 120a and a second electrode end 120b. The first electrode layer 102 and the second electrode layer 108 are electrically connected to the first electrode end 120a and the second electrode end 120b, respectively. The second output unit 130 has a third electrode end 130a and a fourth electrode end 130b. The second electrode layer 108 and the third electrode layer 114 are electrically connected to the third electrode end 130a and the fourth electrode end 130b, respectively.

In other words, a first photovoltaic cell unit U1 constituted by the first electrode layer 102, the first light absorption layer 106, and the second electrode layer 108 and a second photovoltaic cell unit U2 constituted by the second electrode layer 108, the second light absorption layer 112, and the third electrode layer 114 are connected in parallel (parallel connection). Therefore, the carriers generated after the first light absorption layer 106 absorbs light are output to the first output unit 120 through the first electrode layer 102 and the second electrode layer 108 to store the generated electric energy. The carriers generated after the second light absorption layer 112 absorbs light are output to the second output unit 130 through the second electrode layer 108 and the third electrode layer 114 to store the generated electric energy. The first and second output units 120, 130 can be connected to other circuits or electronic devices so as to provide electric energy to drive the circuits or the electronic devices.

Accordingly, the first photovoltaic cell unit U1 and the second photovoltaic cell unit U2 of the present embodiment are connected in parallel. The electrode layers of the stacked photovoltaic cell module are connected as shown in FIG. 2. That is, the first electrode layer 102 of the first photovoltaic cell unit U1 is electrically connected to the first electrode end 120a of the first output unit 120 (i.e. a positive electrode end) and the second electrode layer 108 is electrically connected to the second electrode end 120b of the first output unit 120 (i.e. a negative electrode end). The second electrode layer 108 of the second photovoltaic cell unit U2 is electrically connected to the third electrode end 130a of the second output unit 130 (i.e. a negative electrode end), and the third electrode layer 114 is electrically connected to the fourth electrode end 130b of the second output unit 130 (i.e. a positive electrode end).

In the present embodiment, the first photovoltaic cell unit U1 and the second photovoltaic cell unit U2 are each electrically connected to a corresponding output unit. Thus, the current-matching between the first and the second photovoltaic cell units U1, U2 does not need to be considered. In other words, the first and the second photovoltaic cell units U1, U2 in the present embodiment are merely required to reach the maximum light absorption rate respectively so as to generate the maximum output current individually.

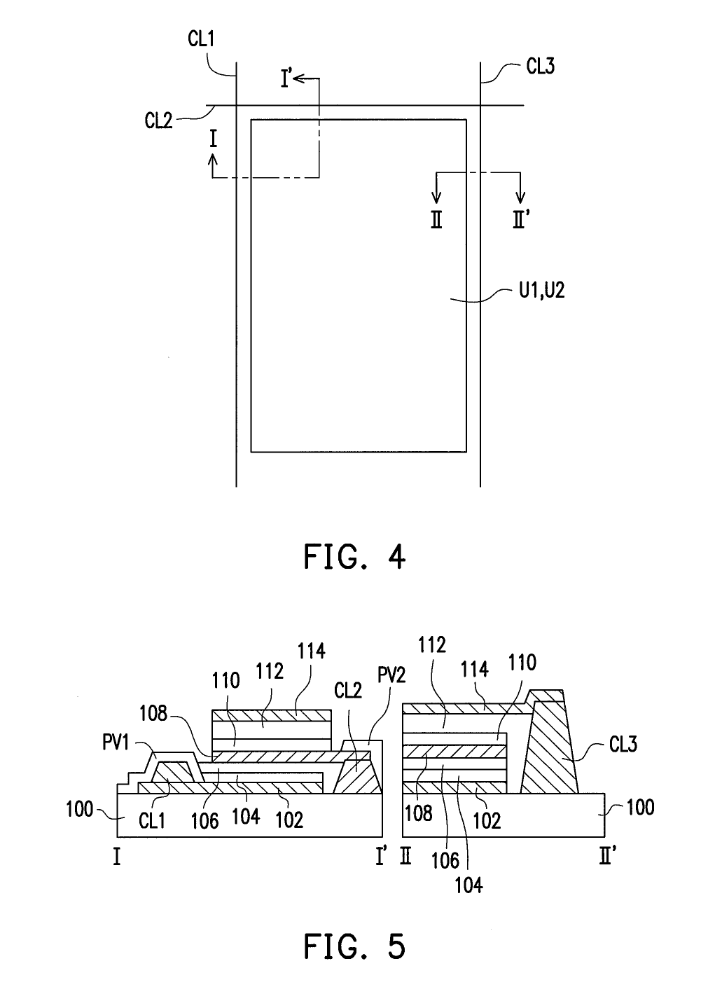

According to the present embodiment, the first electrode layer 102, the second electrode layer 108, and the third electrode layer 114 of the photovoltaic cell module are electrically connected to the electrode ends of the corresponding output devices respectively by using the designs shown in FIGS. 4 and 5.

FIG. 4 illustrates a schematic top view of a stacked photovoltaic cell module according to an embodiment of the invention. FIG. 5 is a cross-sectional diagram taken along line I-I′ and line II-II′ in FIG. 4. Referring to FIGS. 4 and 5, the stacked photovoltaic cell module in the present embodiment includes a first photovoltaic cell unit U1, a second photovoltaic cell unit U2, a first conductive line CL1, a second conductive line CL2, and a third conductive line CL3. The first photovoltaic cell unit U1 and the second photovoltaic cell unit U2 are stacked together.

The first conductive line CL1 is connected to the first electrode layer 102 for the first electrode layer 102 of the first photovoltaic cell unit U1 to electrically connect with the first output unit 120 (the first electrode end 120a). The second conductive line CL2 is connected to the second electrode layer 108 for the second electrode layer 108 of the first photovoltaic cell unit U1 to electrically connect with the first output unit 120 (the second electrode end 120b). To prevent short-circuit between the first conductive line CL1 and the second conductive line CL2, a passivation layer PV1, is further covering the first conductive line CL1, and is further disposed between the first conductive line CL1 and the second conductive line CL2.

The second conductive line CL2 is additionally connected to the second electrode layer 108 of the second photovoltaic cell unit U2, such that the second electrode layer 108 of the second photovoltaic cell unit U2 is electrically connected to the second output unit 130 (the third electrode end 130b). The third conductive line CL3 is connected to the third electrode layer 114 for the third electrode layer 114 of the second photovoltaic cell unit U2 to electrically connect with the second output unit 130 (the fourth electrode end 130b). To prevent short-circuit between the second conductive line CL2 and the third conductive line CL3, a passivation layer PV2, is further covering on the second conductive line CL2, and is further disposed between the second conductive line CL2 and the third conductive line CL3.

According to the present embodiment, since the second conductive line CL2 is electrically connected to the second electrode layer 108 of the first photovoltaic cell unit U1 and the second electrode layer 108 of the second photovoltaic cell unit U2, the second conductive line CL2 can be connected to a ground voltage. Additionally, the first conductive line CL1 and the third conductive line CL3 are electrically connected to the first output unit 120 and the second output unit 130 respectively.

### EXEMPLARY EMBODIMENT AND COMPARATIVE EMBODIMENT

In order to illustrate the stacked photovoltaic cell module has favorable output current and output power comparing to those of the traditional photovoltaic cell module, an exemplary embodiment and a comparative embodiment are provided below.

A structure of the stacked photovoltaic cell module in the present exemplary embodiment is depicted in FIG. 1. Here, the first electrode layer 102 is fabricated using an ITO, the first carrier transport layer 104 is fabricated with PEDOT PSS having a thickness of about 30 nm, the first light absorption layer 106 is fabricated using a poly(3-hexylthiophene):[6,6]-phenyl-C61-butyric acid methyl ester (P3HT [60]PCBM) light absorbing material having a thickness of about 70 nm and absorbing light beams ranging from about 300 nm to about 700 nm. The second electrode layer 108 is fabricated using silver having a thickness of about 15 nm, the second carrier transport layer 110 is fabricated using a ZnO carrier transport material and having a thickness of about 120 nm, and the second light absorption layer 112 adopts a PCPDTBT:[70]PCBM light absorbing material having a thickness of about 70 nm and absorbing light beams ranging from about 600 nm to about 1100 nm. Particularly, the second carrier transport layer 110 and the second light absorption layer 112 of the present embodiment satisfy Φ1+Φ2−2π(n1D1+n2D2)/λ=2 mπ. Herein, Φ1 represents the reflective phase difference between the second light absorption layer and the third electrode layer, Φ2 represents the reflective phase difference between the second carrier transport layer and the second electrode layer, λ represents the absorption wavelength of the second light absorption layer and m represents 0 or an integer. Furthermore, the first photovoltaic cell unit U1 and the second photovoltaic cell unit U2 are connected in parallel in the stacked photovoltaic cell module of the present exemplary embodiment.

A structure of a photovoltaic cell module in the comparative embodiment is similar to that in the above exemplary embodiment. However, the two photovoltaic cell modules are different in that the second carrier transport layer 110 of the comparative embodiment has a thickness of about 30 nm. Thus, in the comparative embodiment, the thickness and the refraction index of the second carrier transport layer 110 and the second light absorption layer 112 do not satisfy Φ1+Φ2−2π(n1D1+n2D2)/λ=2 mπ. Furthermore, the first photovoltaic cell unit U1 and the second photovoltaic cell unit U2 in the stacked photovoltaic cell module of the comparative embodiment are connected in parallel.

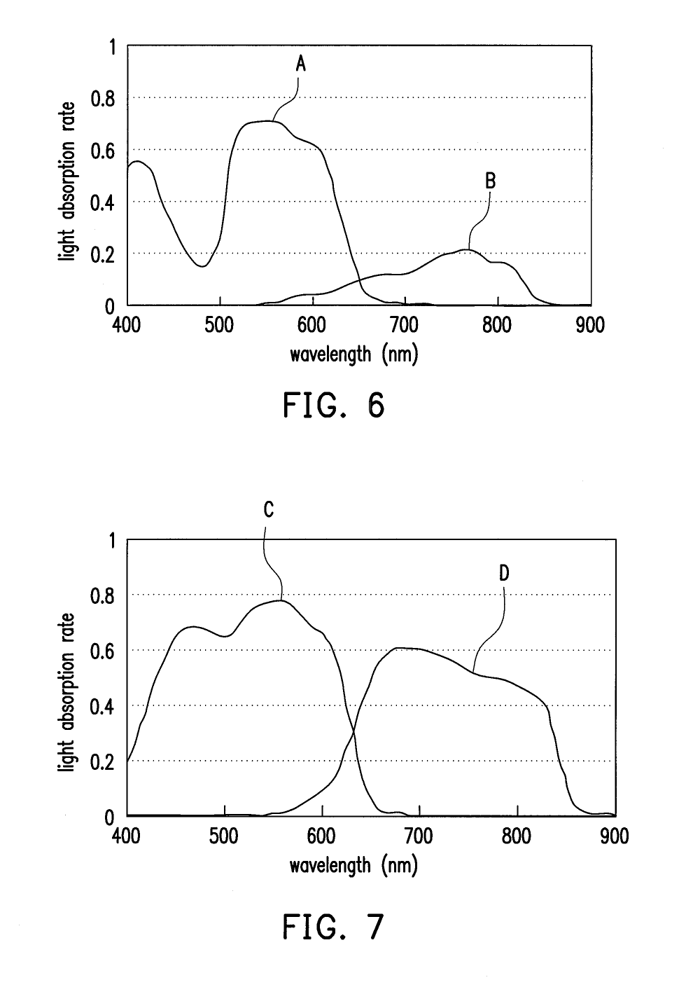

FIG. 6 is a curve diagram showing a light absorption rate and an absorption wavelength of a photovoltaic cell module in the comparative embodiment. Referring to FIG. 6, curve A is a curve representing a light absorption rate and an absorption wavelength of a first light absorption layer in the comparative embodiment, and curve B is a curve representing a light absorption rate and an absorption wavelength of a second light absorption layer in the comparative embodiment. As depicted in FIG. 6, the absorption of the second light absorption layer (curve B) is substantially lower than the absorption of the first light absorption layer (curve A) in the comparative embodiment. This is due to the fact that the second photovoltaic cell unit U2 in the comparative embodiment does not includes an optical resonance cavity, such that the light absorption of the second light absorption layer is clearly lower.

Accordingly, as the light absorption of the second light absorption layer. (curve A) in the comparative embodiment is substantially lower than the light absorption of the first light absorption layer (curve B), the output current of the second photovoltaic cell unit (having the second absorption layer) in the photovoltaic cell module in the comparative embodiment is clearly lower than that of the first photovoltaic cell unit (having the first absorption layer).

FIG. 7 is a curve diagram showing a light absorption rate and an absorption wavelength of a photovoltaic cell module in the present exemplary embodiment. Referring to FIG. 7, curve C is a curve representing a light absorption rate and an absorption wavelength of a first light absorption layer in the present exemplary embodiment, and curve D is a curve representing a light absorption rate and an absorption wavelength of a second light absorption layer in the present exemplary embodiment. As depicted in FIG. 7, the absorption of the second light absorption layer (curve D) in the present exemplary embodiment is substantially higher than the absorption of the second light absorption layer (curve B) in the comparative embodiment. This is due to the fact that the second photovoltaic cell unit U2 in the present exemplary embodiment includes an optical resonance cavity, such that the light absorption of the second light absorption layer of the second photovoltaic cell unit U2 is clearly higher.

In addition, in the present exemplary embodiment, two photovoltaic cell units are connected in parallel in the photovoltaic cell module; that is, the two photovoltaic cell units are electrically connected to the corresponding output units respectively. Therefore, the output current-matching is not required between the two photovoltaic cell units. In other words, the two photovoltaic cell units can output the output currents individually. As a consequence, the total output current of the photovoltaic cell module in the present embodiment is higher than the total output power of the photovoltaic cell module in the comparative embodiment. Here, the total output current (the total output power) of the photovoltaic cell module in the present embodiment has a about 61% increase comparing to the total output current (the total output power) of the photovoltaic cell module in the comparative embodiment.

In summary, in the stacked photovoltaic cell module of the invention, the second carrier transport layer and the second light absorption layer satisfy Φ1+Φ2−2π(n1D1+n2D2)/λ=2 mπ, where Φ1 represents the reflective phase difference between the second light absorption layer and the third electrode layer, Φ2 represents the reflective phase difference between the second carrier transport layer and the second electrode layer, λrepresents the absorption wavelength of the second light absorption layer and m represents 0 or an integer. Thus, an optical resonance cavity is formed between the third electrode layer and the second electrode layer so as to increase the light absorption rate of the second light absorption layer. Additionally, each of the photovoltaic cell units in the stacked photovoltaic cell module of the invention is connected to the corresponding output unit individually. Hence, the first light absorption layer and the second light absorption layer can each reach its maximum light absorption rate when a light beam irradiates the photovoltaic cell module without considering the current-matching between the two photovoltaic cell units, such that the total output power of the stacked photovoltaic cell module can be enhanced.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A stacked photovoltaic cell module, comprising:
a substrate;
a first electrode layer disposed on the substrate;
a first carrier transport layer disposed on the first electrode layer;
a first light absorption layer disposed on the first carrier transport layer;
a second electrode layer disposed on the first light absorption layer;
a first output unit electrically connected to the first electrode layer and the second electrode layer;
a second carrier transport layer disposed on the second electrode layer;
a second light absorption layer disposed on the second carrier transport layer; and
a third electrode layer disposed on the second light absorption layer;
a second output unit electrically connected to the second electrode layer and the third electrode layer,
wherein the second carrier transport layer has a first refraction index n1 and a first thickness D1, the second light absorption layer has a second refraction index n2 and a second thickness D2, and the second carrier transport layer and the second light absorption layer satisfy:
Φ1+Φ2−2π(n1D1+n2D2)/λ=2 mπ,
where
Φ1 represents a reflective phase difference between the second light absorption layer and the third electrode layer,
Φ2 represents a reflective phase difference between the second carrier transport layer and the second electrode layer,
λ represents an absorption wavelength of the second light absorption layer, and m represents 0 or an integer.

2. The stacked photovoltaic cell module as claimed in claim 1, wherein the second electrode layer has a reflectivity ranging from about 40% to about 80%.

3. The stacked photovoltaic cell module as claimed in claim 1, wherein the second electrode layer comprises a metal material.

4. The stacked photovoltaic cell module as claimed in claim 1, wherein the second electrode layer has a thickness ranging from about 10 nanometer (nm) to about 25 nm.

5. The stacked photovoltaic cell module as claimed in claim 1, wherein the first light absorption layer and the second light absorption layer comprises an organic light absorption material, respectively.

6. The stacked photovoltaic cell module as claimed in claim 1, wherein one of the first light absorption layer and the second light absorption layer absorbs light ranging from about 300 nm to about 700 nm and the other absorbs light ranging from about 600 nm to about 1100 nm.

7. The stacked photovoltaic cell module as claimed in claim 1, wherein
the first output unit has a first electrode end and a second electrode end, and the first electrode layer and the second electrode layer are electrically connected to the first electrode end and the second electrode end, respectively; and
the second output unit has a third electrode end and a fourth electrode end, and the second electrode layer and the third electrode layer are electrically connected to the third electrode end and the fourth electrode end, respectively.

8. The stacked photovoltaic cell module as claimed in claim 1, further comprising:
a first conductive line connected to the first electrode layer, so as to let the first electrode layer to electrically connect with the first output unit;
a second conductive line connected to the second electrode layer for the second electrode layer to electrically connect with the first output unit and the second output unit; and
a third conductive line connected to the third electrode layer for the third electrode layer to electrically connect with the second output unit.

9. The stacked photovoltaic cell module as claimed in claim 1, wherein the first electrode layer comprises a transparent electrode material.

10. The stacked photovoltaic cell module as claimed in claim 1, wherein the third electrode layer comprises a reflective electrode material.
